(19) United States
(12) Patent Application Publication
(10) Pub. No.: US 2007/0235711 A1
(43) Pub. Date: Oct. 11, 2007

(54) Methods of reducing the bandgap energy of a metal oxide

(75) Inventors: Xiao-Dong Xiang, Danville, CA (US); Wei Shan, Fremont, CA (US)

Correspondence Address: BUCHANAN, INGERSOLL & ROONEY PC, POST OFFICE BOX 1404, ALEXANDRIA, VA, 22313-1404, US

(73) Assignee: Intematix Corporation, Fremont, CA (US)

(21) Appl. No.: 11/731,741

(22) Filed: Mar. 30, 2007

Related U.S. Application Data
(60) Provisional application No. 60/787,857, filed on Mar. 31, 2006.

(51) Int. Cl. H01L 47/00

(52) U.S. Cl. 257/4

(57) ABSTRACT

Disclosed are methods of reducing the bandgap of a metal oxide by alloying a binary oxide with a Group VI element that is isovalent with oxygen. The Group VI element substitutes for at least a portion of the oxygen in the binary oxide to form the alloyed, ternary oxide. Such ternary oxide electrodes are useful as photoelectrodes in photoelectrochemical cells that spontaneously, as a result of solar power, cleave (split) water molecules to produce hydrogen gas. Exemplary ternary metal oxide alloys useful in the present embodiments include W[(VI)ₓO₁₋ₓ]₃ and Ti[(VI)ₓO₁₋ₓ]₂, and the Group VI element may be S, Se, and Te, and combinations thereof.

### BACKGROUND OF THE INVENTION

This application claims priority to U.S. Provisional Application No. 60/787,857, filed Mar. 31, 2006, the contents of which are herein incorporated by reference in their entirety.

### FIELD OF THE INVENTION

Embodiments of the present invention are directed in general to the production of hydrogen from water using photoelectrochemical cells (PECs).

### DESCRIPTION OF THE RELATED ART

In the simplest terms, the principle of photoelectrochemical water decomposition is based on the conversion of light energy into electricity within a cell involving two electrodes immersed in an aqueous electrolyte. At least one of the electrodes is a semiconductor, and capable of absorbing light. Electricity produced by this semiconducting electrode is used for water electrolysis. The performance of PECs (as characterized by the conversion efficiency of solar energy, and consequently the production of hydrogen) very much depends on the semiconducting and electrochemical properties of the photoelectrode used in the hydrolysis process.

It is known that light production can be the result of intrinsic ionization within a given semiconducting material across the bandgap, leading to the formation of electrons in the conduction band and holes in the valence band:
2hv→2e⁻+2h⁺, (1)
where h is the Planck's constant, v the frequency, e⁻ represents the electron, and h⁺ represents the electron hole. Reaction (1) may take place when the energy of the photons (hv) is equal to or greater than the bandgap energy. An electric field at the electrode/electrolyte interface is required in order to avoid recombination of these charge carriers. This may be achieved through modification of the potential at the electrode/electrolyte interface. The light-induced electron holes result in the splitting of water molecules into gaseous oxygen and hydrogen ions according to the following equation:
2h⁺+H₂O(liquid)→½O₂(gas)+2H⁺. (2)
This process takes place at the photo-anode/electrolyte interface. Gaseous oxygen evolves at the photo-anode and the hydrogen ions created there migrate to the cathode through the internal circuit (aqueous electrolyte). Simultaneously, the electrons generated as a result of Reaction (1) at the photo-anode, are transferred over the external circuit to the cathode, resulting in the reduction of hydrogen ions into gaseous hydrogen:
2H⁺+2e⁻→H₂(gas). (3)
Accordingly, the overall reaction of the PEC may be expressed in the form:
2hv+H₂O(liquid)→½O₂(gas)+H₂(gas). (4)
Reaction (4) takes place when the energy of the photons absorbed by the photo-anode is equal to or larger than Eₜ, the threshold energy:
Eₜ=ΔG⁰(H₂O)/2N_{A}, (5)
where ΔG⁰(H₂O) is the standard free enthalpy per mole of Reaction (4); ΔG⁰(H₂O)=237.141 kJ/mol; N_{A} is Avogadro's number, 6.022×10²³ mol⁻¹. This yields:
Eₜ=hv=1.23 eV. (6)
According to Eq. (6), the electrochemical decomposition of water is possible when the electromotive force of the cell (EMF) is equal to or greater than than 1.23 V.

The oxygen producing half-reaction typically requires an additional over-potential (greater than about 0.275 V) and the hydrogen-producing half-reaction requires an additional over-potential (greater than about 0.050 V) to proceed at a reasonable rate. See, for example, B. O. Seraphin, in Solar Energy Conversion, B. O. Seraphin, ed. (Springer, Berlin, 1979). For a single-photoelectrode cell, either the cell's electron-accepting state or its electron-donating state is at the bulk Fermi energy, which is typically 0.050 to 0.200 eV away from a band edge depending upon the nature of the doping of that particular material.

These observations conspire to define the requirements of a photoelectrode in terms of semiconducting and electrochemical properties, and their impact on the performance of PECs. See, for example, A. Fujishima and K. Honda in Nature, 238, 37(1972), and J. Nowotny, in Science of Ceramic Interfaces, J. Nowotny, ed. (Elsevier, Amsterdam, 1991), p. 79. In summary, the semiconducting and electrochemical requirements that should be substantially satisfied may be delineated as follows:
1. Their conduction and valence band edges can be made to straddle the H⁺/H₂ and O₂/H₂O redox potentials;
2. They can be fabricated with the optimal bandgap of about 2.0 eV; and
3. They are expected to exhibit superior corrosion resistance compared to other semiconductors of similar energy gaps.

Most inorganic semiconductors have the potential for efficient photo-electrochemical (PEC) hydrogen generation due to their favorable bandgaps. However, the unacceptably high corrosion rates inhibit those materials for practical purposes. More stable materials such as metal oxides, unfortunately, do not capture a sufficient portion of the solar spectrum due to their large bandgaps and thus have rather low efficiencies. See, for example, T. Bak, J. Nowotny, M. Rekas, and C. C. Sorrell, in Int. J. Hydrogen Energy, 27, 991(2002).

Thus, what is needed in the art is a semiconducting material that can satisfy the three above-mentioned requirements in a PEC application.

### SUMMARY OF THE INVENTION

In one embodiment, the present invention relates to a photoelectrode comprising a ternary metal oxide alloy in which at least a portion of the oxygen in a binary metal oxide is replaced with an isovalent Group VI element.

In another embodiment, the present invention relates to a photoelectrochemical device for electrolysis of water to produce hydrogen comprising a photoelectrode comprising a ternary metal oxide alloy in which at least a portion of the oxygen in a binary metal oxide is replaced with an isovalent Group VI element, a counter electrode comprising a metal, and an electrolyte in an aqueous solution.

In yet another embodiment, the present invention relates to a method of reducing the bandgap of a metal oxide electrode for use in a photoelectrochemical cell (PED). The method comprises a) depositing a binary metal oxide on a substrate, and b)alloying the binary metal oxide to form a ternary metal oxide by replacing as least some of the oxygen atoms of the binary metal oxide with an isovalent, Group VI element.

Other systems, methods, features and advantages of the present invention will be or become apparent to one with skill in the art upon examination of the following drawings and detailed description. It is intended that all such additional systems, methods, features and advantages be included within this description, be within the scope of the present invention, and be protected by the accompanying claims.

### BRIEF DESCRIPTION OF THE DRAWINGS

FIG. 1 is a band diagram of W(SₓO₁₋ₓ)₃ at the vicinity of the center of Brillouin zone, showing that the interaction between the localized S states (dashed line) and the extended valence band states (dot-dashed line) strongly modifies the valence band structure while the conduction band remains nearly uneffected.

FIG. 2 shows the results of a secondary ion mass spectroscopy (SIMS) measurement on a sample W(SₓO₁₋ₓ)₃, showing the distribution of the isoelectronic S.

FIG. 3 depicts the spectral features associated with the bandgap transitions from W(SₓO₁₋ₓ)₃ and WO₃; the lower curve shows that the optical transition energy associated with the bandgap of W(SₓO₁₋ₓ)₃ is shifted toward lower energy relative to WO₃.

FIG. 4 plots the redox potentials of H⁺/H₂ and O₂/H₂O relative to the vacuum level and as a function of pH, with respect to the conduction band and the valence band of TiO₂; the plot shows that additional over potentials are required for water cleavage.

FIG. 5A is a plot of the spectral irradiance of the sun shown in the UV-Visible-NIR regions under air mass 1.5 global conditions, where only less than 4% of total solar emission can be absorbed by TiO₂ while around 37.3% of total solar irradiance (the yellow area) is useful for spontaneous photo-electrolysis using a semiconductor electrode with an optimal bandgap of 2.0 eV.

FIG. 5B shows that a conversion efficiency of up to 21 percent can be theoretically achieved using an Ti(SₓO₁₋ₓ)₂ alloy having a bandgap energy of 2.2 eV as semiconductor electrode in PEC cells (based on the Shockley-Quiesser model).

### DESCRIPTION OF THE PREFERRED EMBODIMENT

Embodiments of the present invention are directed to novel types of ternary semiconducting oxide alloys having a reduced bandgap energy, the reduced bandgap being useful (among other applications) in photoelectrochemical cells. The enhancement is achieved by incorporating a few atomic percent of a Group VI element which is isovalent with oxygen into a binary metal oxide to form a ternary alloy. Preferably the bandgap energy of the ternary metal oxide alloy is smaller by at least 10 percent relative to the unsubstituted binary metal oxide. Photoelectrodes made from these semiconducting alloy materials provide better conversion efficiency for splitting water, and longer operational lifetime for hydrogen production. The present ternary alloys, and methods of their production, are useful with any semiconducting oxide whose bandgap can be modified by the introduction of an isovalent Group VI element.

According to the present embodiments, Group VI elements which may be used include S, Se and Te, or combinations thereof. At least a portion of the oxygen in a binary metal oxide is substituted by the Group VI element to form an alloyed, ternary oxide in order to reduce the bandgap of the metal oxide. Typically a few atom percent of the Group VI element is substituted for oxygen in the metal oxide. For example, 10 atomic percent of less of Group VI element may be substituted for oxygen in the metal oxide, or 5 atomic percent of less of Group VI element, or 1 atomic percent or less of Group VI element.

In general, embodiments of the present invention involve incorporating Group VI element into a metal oxide represented by the formula MO_{y} to form an M[(VI)ₓO₁₋ₓ]_{y} alloy. M represents a metallic element, and y gives the stoichiometry of the compound. Any metallic element may be used in MO_{y} such that substitution of at least a portion of the oxygen with Group VI element results in an alloy with a reduced bandgap relative to the starting MO_{y}. Exemplary metal oxides which may be used include WO₃ and TiO₂. Exemplary ternary metal oxide alloys which may be produced include W(SₓO₁₋ₓ)₃ and Ti(SₓO₁₋ₓ)₂.

The M(SₓO₁₋ₓ)_{y} System

One embodiment of the present invention involves incorporating sulfur (S) into a metal oxide represented by the formula MO_{y} to form an M(SₓO₁₋ₓ)_{y} alloy. Here M represents a metallic element, and y gives the stoichiometry of the compound. Replacing the oxygen anions in a metal oxide with isovalent sulfur atoms (the sulfur atoms having a different electronegativity and atomic size from the oxygen atoms they are replacing) is contemplated to induce localized states (E_{S}) within the bandgap of the metal oxide in the dilute doping regime. Incorporation of a few atomic percent (e.g., 10 atomic percent or less) of S into a metal oxide such as WO₃ for instance, significantly modifies the valence band structure of the host material. Due to a strong band anticrossing interaction, the introduction of an alloying element causes a localized bond to be formed, wherein the localized bond then interacts with extended states that are close to it in energy. See, for example, W. Shan, W. Walukiewicz, J. W. Ager III, E. E. Haller, J. F. Geisz, D. J. Friedman, J. M. Olson, and S. R. Kurtz in Phys. Rev. Lett. 82, 1221(1999).

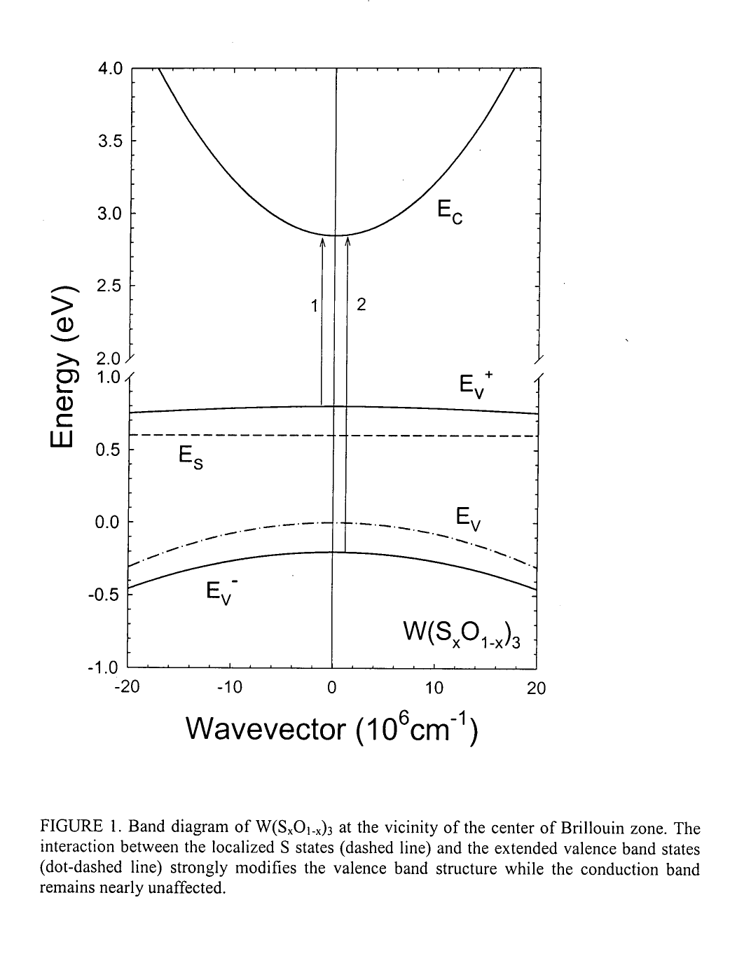

In the case of WO₃, the S localized level is located about 0.6 to about 1.0 eV above the valence band edge. When S is incorporated at a certain percentage level, the bandgap is reduced from the WO₃ value of about 2.85 eV to about 2.0 eV, as shown in FIG. 1. This bandgap reduction (desirable for higher PEC efficiency) occurs primarily by a shift in the valence band. The top-most valence band (E_{y}) of WO₃ evolves into two non-parabolic sub-bands E_{y}⁻ and E_{y}⁺ in a W(SₓO₁₋ₓ)₃ alloy, where x represents the mole fraction of S in the material. The upward shift of E_{y}⁺ relative to the bottom of the conduction band represents the reduction of the fundamental band gap, while the energy position of the conduction band is not strongly affected.

The above also pertains to any semiconducting oxide whose band gap may be modified by the introduction of an isovalent Group VI element (e.g., S, Se, and Te), leading to a favorable band alignment with respect to the H⁺/H₂ and O₂/H₂0 redox potentials.

Synthesis of Isovalent Group VI Element-Containing Metal Oxide Alloys

Another embodiment of the present invention is directed to a process of synthesizing M[(VI)ₓO₁₋ₓ]_{y} alloys. The synthesis process may utilize a variety of different methods, but it is preferable to synthesize a metal oxide MO_{y} by thermal annealing of an “intermediate” MO_{y} compound, and then alloying the thermally annealed MO_{y} with a Group VI element to form a ternary alloy containing the isovalent Group IV element.

Synthesis of the MO_{y} intermediate may be accomplished, for example, by ion beam sputtering (IBS), which deposits a metal oxide precursor in the form of a thin film on a substrate. The substrate material may be glass, or sapphire, or any other material appropriate for the thin film deposition of a metal oxide. The thickness of the deposited film typically ranges from about one nanometer to ten micrometers but any appropriate thickness of the deposited film may be used.

The post-deposition, thermal annealing of the metal oxide intermediate is done to effect a better crystalline quality in the thin film. This heating step is performed at a temperature lower than the melting point of either the metal oxide, or the substrate on which the metal oxide layer had been deposited. The annealing temperature generally is between about 500 to 1000° C., and the heating duration generally varies from about 30 minutes to three hours, typically under continuous O₂ flow conditions.

Alloying the annealed metal oxide film with a Group VI element isovalent to oxygen may be carried out, for example, by sealing a metal oxide wafer in an ampoule with an ingot of the desired Group VI element (e.g., S, Se, or Te) under vacuum conditions. The wafer is generally placed near one end in the ampoule and the ingot near the other end. The ampoule is typically then heated in a two-temperature-zone oven with the ingot end positioned within the higher temperature zone of the oven. The desired partial pressure of the Group VI element in this zone of the oven allows the alloying with the oxide to occur. The atomic percentage of the Group VI element that the resultant alloy ends up having is generally controlled by the exposure time of the annealed oxide to the Group VI source.

Uses of Group VI Element-Containing Metal Oxide Alloys

The Group VI element-containing metal oxide alloys are useful, for example as photoelectrodes in photoelectochemical cells such as those used for splitting water to produce hydrogen gas. It is contemplated, however, that the Group VI element-containing metal oxide alloys may be employed in any application which would benefit from the properties of these materials.

When using a photoelectrochemical cell, the production of oxygen and hydrogen via photoeletrolysis occurs in a cell in which the electrolyte may be acidic, alkaline or neutral. The design of the electrodes and the arrangement of the cell we be determined, at least in part, by the nature of the electrolyte. Generally, the generation of hydrogen using a photoelectrochemical cell requires a photoelectrode, and at least one counter electrode to the photoelectrode. The photoelectrode and its counter electrode are situated in a suitable container having an electrolyte in an aqueous solution, which provides the source of hydrogen, and suitable ionic species for facilitating the electrolysis. The photoelectrode comprises the Group VI-element-containing metal oxide alloy. Typically, a metal electrode such as Pt or Ni is utilized as the counter electrode, although any suitable material may be employed for the counter electrode.

### EXAMPLES

### Example 1

### Sulfur-Induced Bandgap Reduction in a W(SₓO₁₋ₓ)₃ Alloy

WO₃ thin films with thickness ranging from about 200 nm to about 2000 nm were deposited by ion beam sputtering (IBS). Two types of substrates were used for this thin film deposition: 1) a SnO₂-coated glass, and 2) sapphire. The sputtering source for the WO₃ thin films was a WO₃ target. The substrates are placed in the deposition chamber with the nominal surface temperature around 300K. The deposition was carried out by sputtering WO₃ target with target bombardment provided by an Ar plasma. The deposition rate was controlled by tuning the RF power to the plasma, and monitored by the change in the thickness of the deposited film. Post-deposition annealing was performed in a heating tube with a constant oxygen flow and at temperature of about 550° C. The crystal structure of the thin-film samples was examined and characterized using X-ray diffraction (XRD). The XRD pattern indicated that the WO₃ thin films were poly-crystalline and predominantly monoclinic.

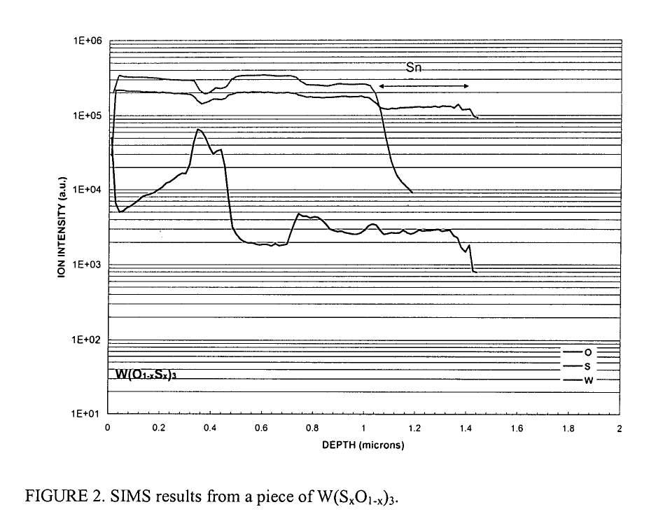

Alloying S with the WO₃ thin film was accomplished by sulfurization and the methods previously described in this disclosure. The annealed WO₃ films were sulfurized for about one hour at 400° C. for one hour, and the resulting S distribution (profile), was measured by secondary ion beam spectroscopy (SIMS). The SIMS results are shown in FIG. 2.

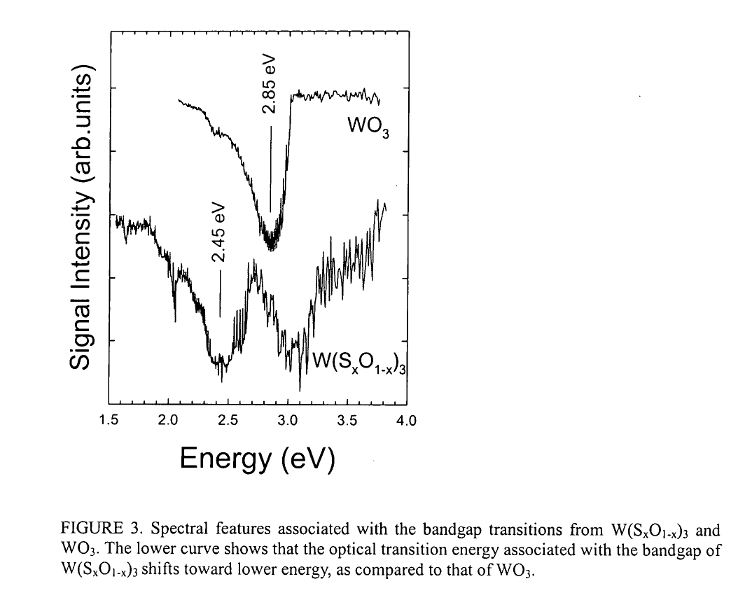

FIG. 3 shows a comparison the optical spectra from an annealed W(SₓO₁₋ₓ)₃ alloy compared to a control (in this case, un-annealed WO₃, or WO₃ with no sulfur substituting for oxygen), the measurement made by photomodulated transmission spectroscopy. The control sample was taken from the same wafer as that WO₃ which had undergone sulfurization. The spectral features associated with the fundamental bandgap observed from the two samples indicate that the transition energy required to transit the bandgap of W(SₓO₁₋ₓ)₃ is smaller than that required of the pure, binary compound WO₃. These results are consistent with the prediction that bandgap reduction may be induced by the incorporation of isoelectronic Group VI elements into semiconducting metal oxides to form M(SₓO₁₋ₓ)_{y} alloys, the Group VI elements having substantially different electronegativities and atomic sizes from the oxygen atoms that they are replacing.

### Example 2

### Ti(SₓO₁₋ₓ)₂ System for Spontaneous Water Photo-Electrolysis

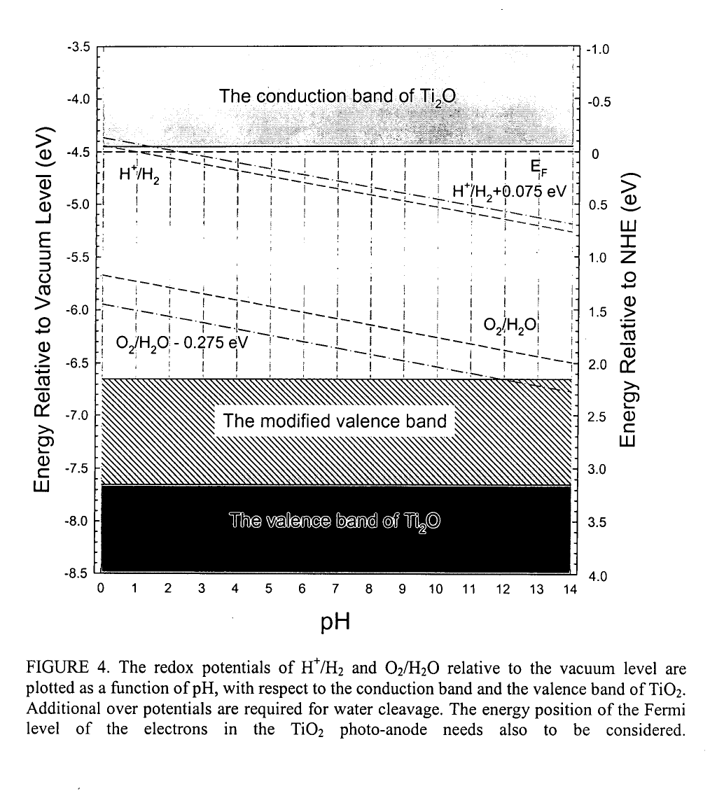

Titanium dioxide (TiO₂) is a semiconducting metal oxide that can function as a photoanode in a PEC cell spontaneously splitting water by photo-electrolysis using sun light. Shown in FIG. 4 are the energy positions relative to the vacuum level of the redox potentials for the hydrogen-producing half-reaction, and the redox potentials of the oxygen-producing half-reaction, as a function of pH value. Although the potential difference of the coupled redox reactions is only about 1.23 eV, the following conditions are also preferred: 1) an additional over potential of about 0.05 eV to about 0.075 eV; 2) a 0.275 eV hydrogen-producing half reaction and oxygen-producing half-reaction, and 3) a Fermi energy position that is typically about 0.05 to 0.2 eV from the band edges.

These factors considered, spontaneous photo-electrolysis of water by sunlight is contemplated to occur at positions where the bandgap of TiO₂ straddles the required H⁺/H₂ and O₂/H₂O redox potentials, and their respective over potentials, when the Fermi level near the bottom of the conduction band sits above the energy position of the potential for the hydrogen-producing half reaction. However, the large bandgap energy of 3.2 eV of TiO₂ manifests a low conversion efficiency (about 3.4 percent theoretically), and only the ultraviolet portion of the solar spectrum is absorbed. The process is insensitive to the visible spectrum, about 4 percent of the total solar irradiance.

The resolution to this problem is given by an embodiment of the present invention. By replacing oxygen with a few atomic percent of an element having a lower electronegativity and a larger atomic size, such as the Group VI elements S or Se, thereby forming Ti(VIₓO₁₋ₓ)₂ alloys, the bandgap energy of the resulting material is reduced, and the PEC cell can absorb a far greater amount of the solar spectrum. The sulfur level is about 1.0 eV above the valence band of TiO₂ (based on a theoretical estimate). In other words, the bandgap energy may be reduced from about 3.2 eV for TiO₂ to less than 2.2 eV for the sulfur containing alloy synthesized with a modified valence band (FIG. 4). The net effect of substituting sulfur for oxygen shifts the absorption edge of the semiconductor electrode in a PEC cell from about 390 nm in the UV (if TiO₂ is used) to about 560 nm in the visible spectrum.

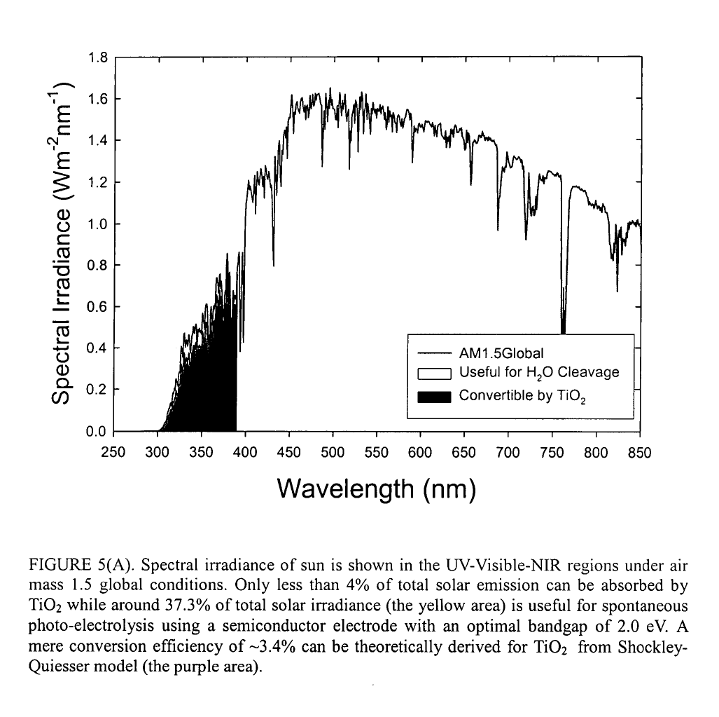

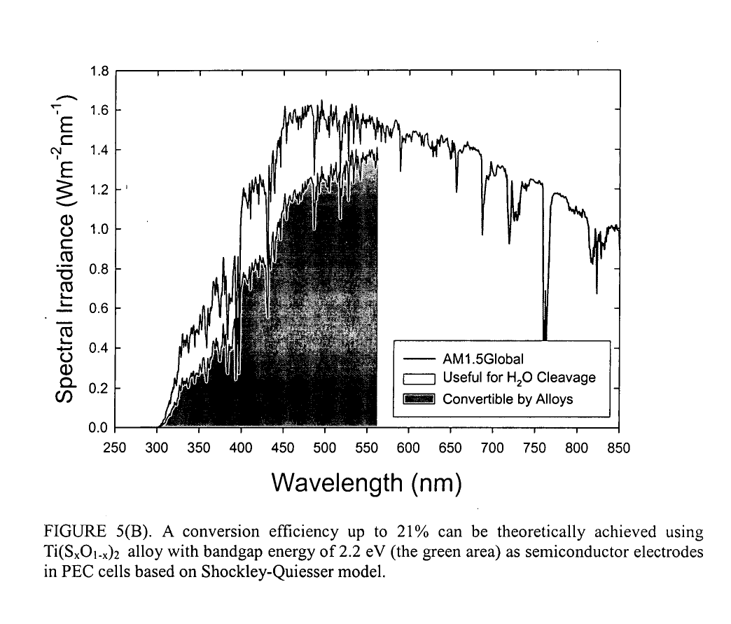

Thus, the absorption of solar emission may be significantly increased to more than 30 percent of total solar irradiance. The theoretical conversion efficiency of solar energy may be vastly improved, from about 3.4% for pure TiO₂ to about 21 percent for the alloy. The effect is illustrated in FIG. 5.

All references cited in this disclosure are incorporated by reference to the same extent as if each reference had been incorporated by reference in its entirety individually.

While the invention has been described in detail and with reference to specific embodiments thereof, it will be apparent to one skilled in the art that various variations and modifications can be made therein without departing from the sprit and scope thereof. All such variations and modifications are intended to be included within the scope of this disclosure and the present invention and protected by the following claims.

What is claimed is:

1. A photoelectrode comprising a ternary metal oxide alloy in which at least a portion of the oxygen in a binary metal oxide is replaced with an isovalent Group VI element.

2. The photoelectrode of claim 1, wherein the photoelectrode has the formula M[(VI)ₓO₁₋ₓ]_{y}, wherein M is a metallic element, (VI) is a Group VI element, 1>x>0 and y≧1.

3. The photoelectrode of claim 1, wherein the bandgap of the ternary metal oxide alloy is less than the bandgap of the unsubstituted binary metal oxide.

4. The photoelectrode of claim 1, wherein the band gap energy of the ternary metal oxide alloy relative to the unsubstituted binary metal oxide is smaller by at least 10 percent.

5. The photoelectrode of claim 1, wherein the Group VI element is selected from the group consisting of S, Se and Te.

6. The photoelectrode of claim 1, wherein the ternary metal oxide alloy is selected from the group consisting of W[(VI)ₓO₁₋ₓ]₃ and Ti[(VI)ₓO₁₋ₓ]₂, (VI) is selected from the group consisting of S, Se and Te, and 1>x>0.

7. The photoelectrode of claim 1, wherein the mole percent of the Group VI element replacing oxygen in the ternary metal oxide alloy is ten percent or less.

8. A method of reducing the bandgap of a metal oxide electrode for use in a photoelectrochemical cell (PED), the method comprising:
a) depositing a binary metal oxide on a substrate;
b) alloying the binary metal oxide to form a ternary metal oxide by replacing as least some of the oxygen atoms of the binary metal oxide with an isovalent, Group VI element.

9. The method of claim 8, further including the step of annealing the binary metal oxide in an oxygen environment prior to alloying the binary metal oxide with the Group VI element.

10. The method of claim 9, wherein the Group VI element is selected from the group consisting of S, Se and Te.

11. The method of claim 8, wherein the ternary metal oxide is selected from the group consisting of W[(VI)ₓO₁₋ₓ]₃ and Ti[(VI)ₓO₁₋ₓ]₂, wherein (VI) is selected from the group consisting of S, Se and Te, and 1>x>0.

12. A photoelectrochemical device for electrolysis of water to produce hydrogen comprising:
a photoelectrode comprising a ternary metal oxide alloy in which at least a portion of the oxygen in a binary metal oxide is replaced with an isovalent Group VI element;
a counter electrode comprising a metal; and
an electrolyte in an aqueous solution.

13. The photoelectrochemical device of claim 12, wherein the photoelectrode has the formula M[(VI)ₓO₁₋ₓ]_{y}, wherein M is a metallic element, (VI) is a Group VI element, 1>x>0 and y≧1.

14. The photoelectrochemical device of claim 12, wherein the bandgap of the ternary metal oxide alloy is less than the bandgap of the unsubstituted binary metal oxide.

15. The photoelectrochemical device of claim 12, wherein the band gap energy of the ternary metal oxide alloy relative to the unsubstituted binary metal oxide is smaller by at least 10 percent.

16. The photoelectrochemical device of claim 12, wherein the Group VI element is selected from the group consisting of S, Se and Te.

17. The photoelectrochemical device of claim 12, wherein the ternary metal oxide alloy is selected from the group consisting of W[(VI)ₓO₁₋ₓ]₃ and Ti[(VI)ₓO₁₋ₓ]₂, (VI) is selected from the group consisting of S, Se and Te, and 1>x>0.

18. The photoelectrode of claim 1, wherein the mole percent of the Group VI element replacing oxygen in the ternary metal oxide alloy is ten percent or less.
